(19) United States
(12) Patent Application Publication
(10) Pub. No.: US 2006/0104039 A1
(43) Pub. Date: May 18, 2006

(54) Enclosure for memory cards

(76) Inventor: Yu-Hu Chen, Hsintien City (TW)

Correspondence Address: DELLETT & WALTERS, P. O. BOX 82788, PORTLAND, OR, 97282-0788, US

(21) Appl. No.: 10/987,277

(22) Filed: Nov. 12, 2004

(51) Int. Cl. H05K 5/02; H01R 33/945; H01R 13/66

(52) U.S. Cl. 361/752; 361/759; 439/620

(57) ABSTRACT

A memory card enclosure includes a bottom cover defining therein a first receiving room and having multiple retaining legs formed on a sidewall defining the first receiving room and extending from the sidewall defining the first receiving room to an opposed sidewall defining the first receiving room and a top cover selectively connected to the bottom cover to close the bottom cover and having a second receiving room corresponding to and communicating with the first receiving room of the bottom cover. After a memory card is inserted into the first receiving room, the retaining legs are able to provide an abutting force to the memory card to be urged against the opposed sidewall defining the first receiving room.

### BACKGROUND OF THE INVENTION

1. Field of the Invention

The present invention relates to a memory card enclosure, and more particularly to the memory card enclosure able to receive therein memory cards of different dimensions.

2. Description of Related Art

With reference to FIG. 8, a conventional memory card enclosure is disclosed to have a bottom cover (60) and a top cover (70) pivotally connected to a peripheral edge of the bottom cover (60). The bottom cover (60) has first recessed areas (61) defined in a face of the bottom cover (60) to receive therein first memory cards (62) of a first dimension. The top cover (70) has second recessed areas (71) defined in a face of the top cover (70) to receive therein second memory cards (72) of a second dimension which is different from that of the first dimension.

From this enclosure structure, it is noted that the enclosure can only receive up to two different memory cards (62,72). As the current memory cards are of many different dimensions e.g. CF, XD or SD, due to different designated applications and different capabilities e.g. 64 MB, 128 MB or 256 MB, the enclosure is not sufficient to meet the requirements.

To overcome the shortcomings, the present invention tends to provide an improved memory card enclosure to mitigate the aforementioned problems.

### SUMMARY OF THE INVENTION

The primary objective of the present invention is to provide an improved memory card enclosure to securely receive therein memory cards of different dimensions.

In order to accomplish the aforementioned objective, the memory card enclosure of the present invention includes a bottom cover and a top cover connected to the bottom cover. Retaining legs of resilient material are provided inside the bottom cover of the enclosure such that after memory cards are received inside the enclosure, the retaining legs are able to push the memory cards against inner side walls of the enclosure. Therefore, the enclosure of the present invention is able to securely hold the memory cards of several different dimensions inside the enclosure.

Other objects, advantages and novel features of the invention will become more apparent from the following detailed description when taken in conjunction with the accompanying drawings.

### BRIEF DESCRIPTION OF THE DRAWINGS

FIG. 1 is a schematic view showing the enclosure of the present invention;

FIG. 2 is schematic view showing a different embodiment of the enclosure of the present invention;

FIG. 3 is a schematic view showing still a different embodiment of the enclosure of the present invention;

FIG. 4 is an exploded perspective view showing the components of the enclosure of the present invention;

FIG. 4A is a cross sectional view showing the internal structure of the enclosure of the present invention after assembly;

FIG. 5 is an exploded perspective view showing that a memory card is about to be received in the bottom cover;

FIG. 6 is a perspective view showing the enclosure after assembly;

FIG. 6A is a cross sectional view showing that after the memory card is inserted into the enclosure and the top cover is connected to the bottom cover, the memory card is pushed by the retaining legs against the inner sidewall of the bottom cover;

FIG. 7 is a perspective view showing a different embodiment of the present invention; and

FIG. 8 is a perspective view showing a conventional memory card enclosure.

### DETAILED DESCRIPTION OF THE PREFERRED EMBODIMENT

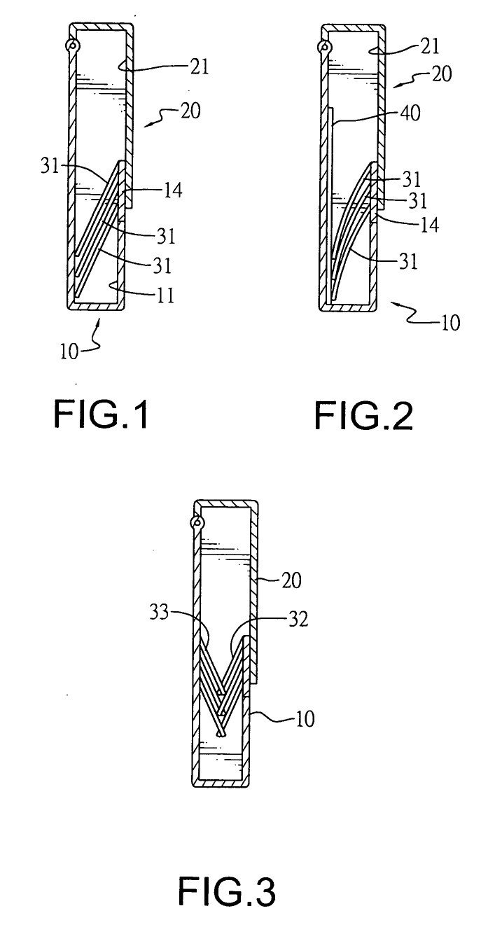

With reference to FIGS. 1 and 2, the enclosure for memory cards of different dimensions includes a bottom cover (10) defining therein a first receiving room (11) and a top cover (20) connected to the bottom cover (10) and defining therein a second receiving room (21). Multiple retaining legs (31) are extended from an inner sidewall defining the first receiving room (11) to an opposed sidewall of the bottom cover (10). Because the retaining legs (31) are made of resilient material, the retaining legs (31) are able to provide abutting force to an object inserted into the bottom cover (10). Therefore, when a memory card (40) is inserted into the first receiving room (11) and extended into the second receiving room (21), the retaining legs (31) are able to push the memory card (40) against the inner sidewall of the bottom cover (10).

With reference to FIG. 3, it is noted that the enclosure of the present invention is substantially the same as that shown in FIG. 1. However, the bottom cover (10) has multiple first retaining legs (32) extending from a first inner sidewall defining the first receiving room (11) in a first direction and second retaining legs (33) extending from a second inner sidewall defining the first receiving room (11) and being opposite to the first inner sidewall in a second direction opposite to the first direction. From the depiction of FIG. 3, it is noted that the first retaining legs (32) and the second retaining legs (33) are inclinedly overlapped with each other in a center of the enclosure of the present invention. Therefore, when a memory card (not shown) is inserted into the bottom cover (10), the memory card will be maintained in the center of the enclosure due to opposite abutting forces provided by the first retaining legs (32) and second retaining legs (33).

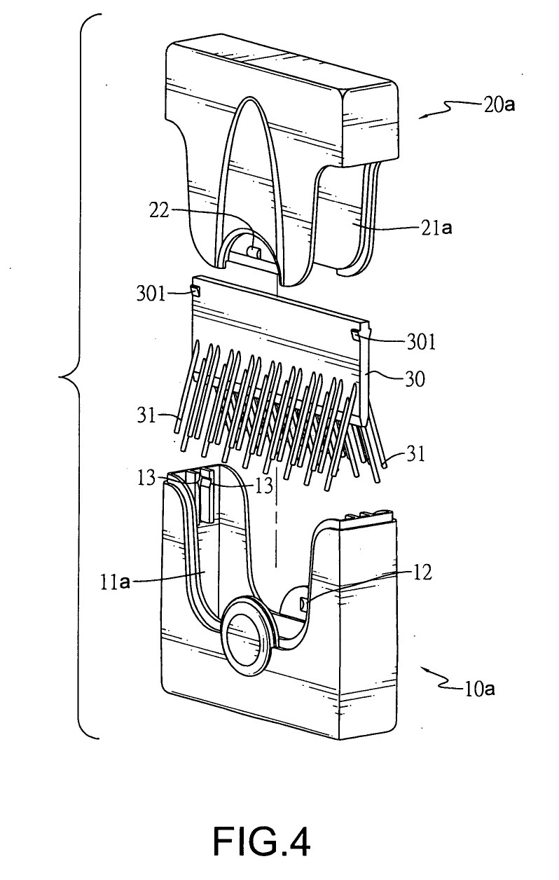

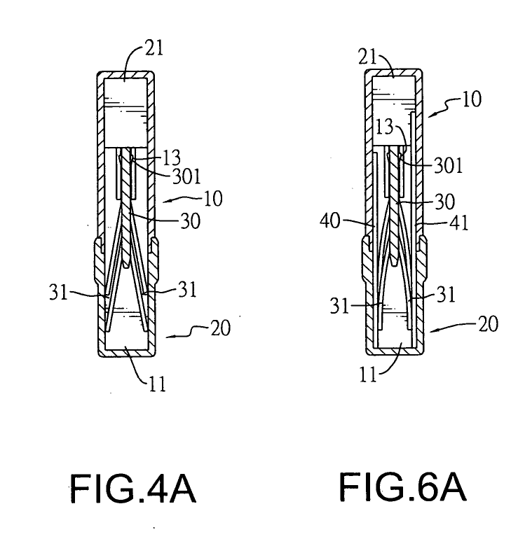

With reference to FIG. 4, it is noted that the enclosure of the present invention now has a bottom cover (10a), a top cover (20a) and a mediate insertion (30).

The bottom cover (10a) is substantially U shaped and has a first receiving room (11a) defined within the bottom cover (10), a retaining hook (12) formed on two opposed sidewalls defining the first receiving room (11a) of the bottom cover (10a) and a male connector (13) formed on two opposed inner sidewalls defining the first receiving room (11a) of the bottom cover (10) and each being sandwiched between the two inner sidewalls having the retaining hooks (12) thereon.

The top cover (20a) has a second receiving room (21a) defined therein to correspond to and communicate with the first receiving room (11a) and a retaining boss (22) formed on two opposed sidewalls of the top cover (20a) to correspond to the retaining hooks (12) of the bottom cover (10a).

The mediate insertion (30) has a plate-like body with two female connectors (301) formed on opposite ends of the body to correspond to the male connector (12) of the bottom cover (10) and multiple retaining legs (31) respectively extending from opposed sidewalls of the body.

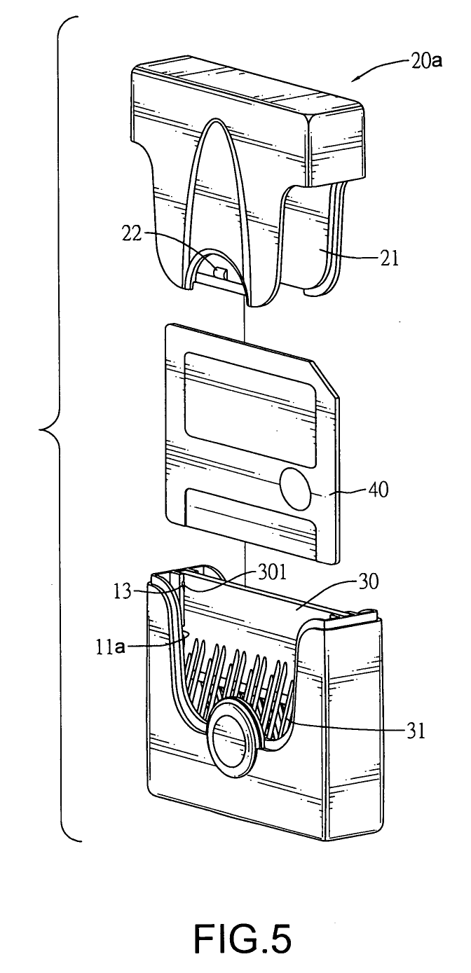

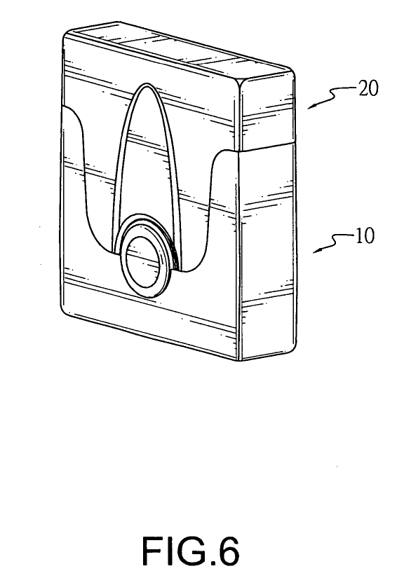

With reference to FIG. 4A, it is noted that the mediate insertion (30) is inserted into the first receiving room (11a) of the bottom cover (10a) to have the male connectors (13) connected to the female connectors (301) of the mediate insertion (30) so as to position the mediate insertion (30) inside the first receiving room (11a) of the bottom cover (10a). Thereafter, it is noted that the retaining legs (31) extending from opposed sidewalls of the plate-like body of the mediate insertion (30) engage with two opposite sidewalls defining the first receiving room (11a) respectively. Therefore, when a memory card (40) as depicted in FIGS. 5, 6 and 6A is inserted into the first receiving room (11a), the retaining legs (31) are able to provide a sufficient abutting force to the memory card (40) so as to push the memory card (40) against the sidewall defining the first receiving room (11a) regardless of the memory card dimension.

After the memory card (40) is inserted into the first receiving room (11a) and abutted by the retaining legs (31), the top cover (20a) is able to connect to the bottom cover (10a) by means of the engagement between the retaining hooks (12) and the retaining bosses (22). Thus the memory card (40) is securely received in the enclosure of the present invention.

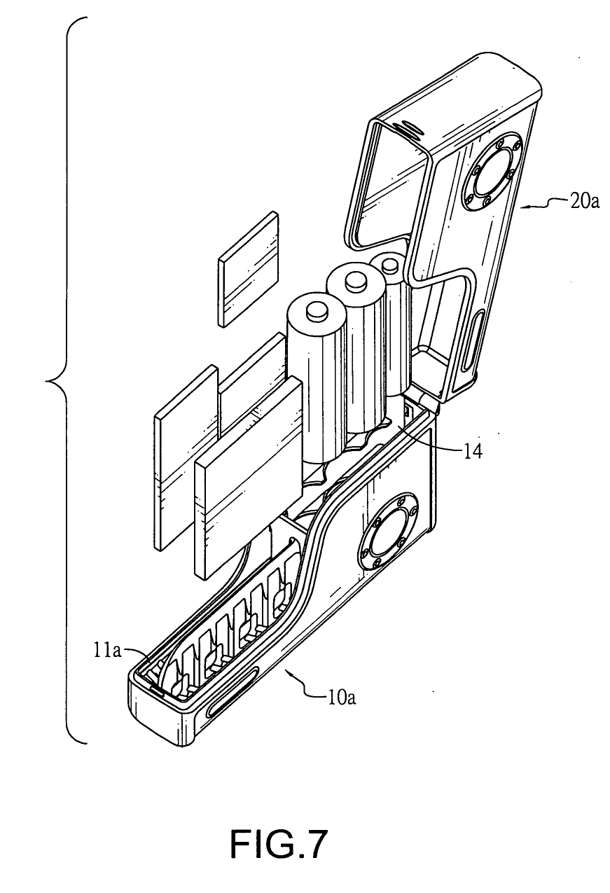

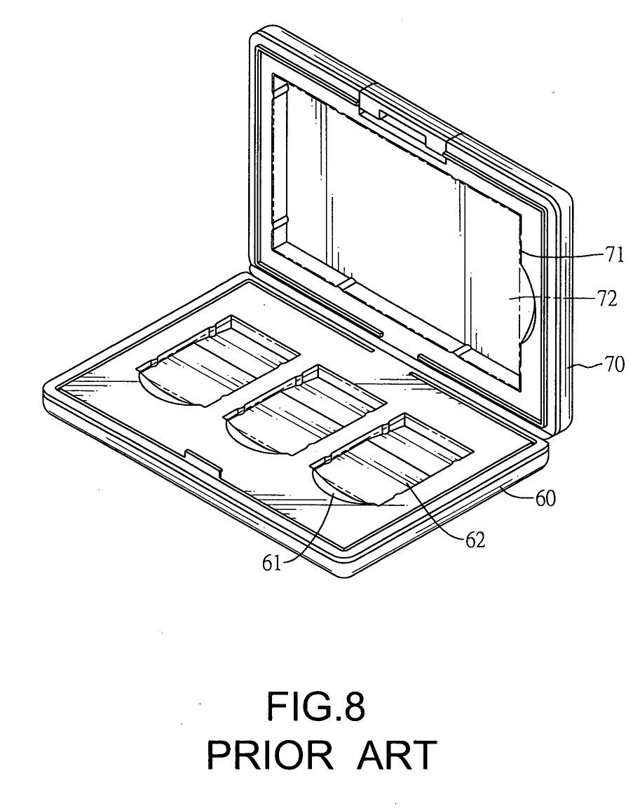

With reference to FIG. 7, it is noted that the bottom cover (10a) of the enclosure of the present invention further has a battery compartment (14) defined in the first receiving room (11a) and divided by a baffle (15) securely formed inside the first receiving room (11a) for receiving therein batteries (not numbered).

With the provision of the retaining legs (31), the user is able to easily store memory cards of different dimensions inside the enclosure. It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A memory card enclosure comprising:
a bottom cover defining therein a first receiving room and having multiple retaining legs formed on a sidewall defining the first receiving room and extending from the sidewall defining the first receiving room to an opposed sidewall defining the first receiving room; and
a top cover selectively connected to the bottom cover to close the bottom cover and having a second receiving room corresponding to and communicating with the first receiving room of the bottom cover,
whereby after a memory card is inserted into the first receiving room, the retaining legs provide an abutting force to the memory card to urge the memory card against the opposed sidewall defining the first receiving room.

2. A memory card enclosure comprising:
a bottom cover defining therein a first receiving room and having multiple first retaining legs formed on a first sidewall defining the first receiving room and second retaining legs formed on a second sidewall opposite to the first sidewall, the first retaining legs extending from the first sidewall to the second sidewall defining the first receiving room and the second retaining legs extending from the second sidewall to the first sidewall to inclinedly overlap with the first retaining legs; and
a top cover selectively connected to the bottom cover to close the bottom cover and having a second receiving room corresponding to and communicating with the first receiving room of the bottom cover,
whereby after a memory card is inserted into the first receiving room, the retaining legs provide an abutting force to the memory card to maintain the memory card in a center of the bottom cover.

3. A memory card enclosure comprising:
a bottom cover defining therein a first receiving room;
a top cover detachably connected to the bottom cover to close the bottom cover, the top cover having a second receiving room defined therein to correspond to and communicate with the first receiving room of the top cover after the top cover is connected to the bottom cover; and
a mediate insertion detachably received in the first receiving room and having multiple retaining legs extending from opposed sidewalls of the mediate insertion,
whereby after a memory card is inserted into the first receiving room, the retaining legs provide an abutting force to the memory card to push the memory card against a sidewall defining the first receiving room of the bottom cover.

4. The memory card enclosure as claimed in claim 3, wherein the bottom cover has a retaining hooks formed on two opposed first sidewalls defining the first receiving room and the top cover has a retaining boss formed on two opposed sidewalls thereof to correspond to and selectively engage with the retaining hook of the bottom cover such that the top cover connects to the bottom cover.

5. The memory card enclosure as claimed in claim 4; wherein the bottom cover has a male connector formed on two second sidewalls defining the first receiving room and each second sidewall is sandwiched by two first sidewalls having thereon the retaining hooks, the mediate insertion has a female connector formed on two sides of the mediate insertion to correspond to and engage with the male connector of the bottom cover such that the mediate insertion is securely retained in the first receiving room of the bottom cover.

6. The memory card enclosure as claimed in claim 5, wherein a baffle is formed inside the first receiving room to define a battery compartment for receiving therein batteries.
